(19) United States
(12) Patent Application Publication
(10) Pub. No.: US 2026/0107375 A1
(43) Pub. Date: Apr. 16, 2026

(54) METHOD FOR FORMING AN ELECTRONIC DEVICE WITH REDUCED WARPAGES

(71) Applicant: JCET STATS ChipPAC Korea Limited, Incheon (KR)

(72) Inventors: YeoJun YUN, Incheon (KR); KyoungHee PARK, Seoul (KR); HeeSoo LEE, Incheon (KR)

(21) Appl. No.: 19/356,208

(22) Filed: Oct. 13, 2025

(30) Foreign Application Priority Data
Oct. 12, 2024 (CN) 202411420146.1

(51) Int. Cl. H05K 1/02; H05K 3/22; H05K 3/28; H05K 3/34

(52) U.S. Cl. CPC H05K 1/0271; H05K 3/225; H05K 3/284; H05K 3/3421; H05K 2201/10522; H05K 2203/085; H05K 2203/1105

(57) ABSTRACT

A method for forming an electronic device is provided. The method comprises: providing a substrate with at least an electronic component mounted thereon; forming a molding layer on the substrate to encapsulate the at least one electronic component; curing the molding layer to transform it into a mold cap; disposing the substrate with the mold cap onto a carrier having air vents passing therethrough; applying laser radiation via a laser source to heat the mold cap and the substrate to a temperature above a predetermined temperature threshold; applying a vacuum pressure to the substrate and the mold cap through the air vents of the carrier such that the substrate and the mold cap are attracted to the carrier to reduce warpage of the mold cap and the substrate generated during the curing step.

### TECHNICAL FIELD

The present application generally relates to semiconductor technology, and more particularly, to a method for forming an electronic device with reduced warpages.

### BACKGROUND OF THE INVENTION

The semiconductor industry is constantly faced with complex integration challenges as consumers want their electronics to be smaller, faster and higher performance with more and more functionalities packed into a single device. Typically, a semiconductor package may be formed by first mounting electronic components onto a substrate via solder bumps, and then forming a mold cap on the substrate to encapsulate the electronic components. The formation of the mold cap may include a curing process of a molding material formed on the substrate, which may be transformed into the mold cap later. The curing process can be conducted by applying a heating process to the entire device to cure the molding material. However, the curing process may induce warpage issues of the substrate and the mold cap due to mismatch in the coefficient of thermal expansion (CTE) between different materials within the device, which may adversely affect device performance and following fabrication processes.

Therefore, a need exists for a method for forming an electronic device with reduced warpages.

### SUMMARY OF THE INVENTION

An objective of the present application is to provide a method for forming an electronic device with reduced warpages.

According to an aspect of the present application, a method for forming an electronic device is provided. The method comprises: providing a substrate with at least an electronic component mounted thereon; forming a molding layer on the substrate to encapsulate the at least one electronic component; curing the molding layer to transform it into a mold cap; disposing the substrate with the mold cap onto a carrier having air vents passing therethrough; applying laser radiation via a laser source to heat the mold cap and the substrate to a temperature above a predetermined temperature threshold; applying, when the temperature of the mold cap and the substrate is above the predetermined temperature threshold, a vacuum pressure to the substrate and the mold cap through the air vents of the carrier such that the substrate and the mold cap are attracted to the carrier to reduce warpage of the mold cap and the substrate generated during the curing step.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1F illustrate various steps of a method for forming an electronic device according to a first embodiment of the present application.

FIG. 2 illustrates a laser radiation step to heat a mold cap and a substrate for forming an electronic device according to a second embodiment of the present application.

FIG. 3 illustrates a laser radiation step to heat a mold cap and a substrate for forming an electronic device according to a third embodiment of the present application.

FIG. 4 illustrates a cooling step to cool down a mold cap and a substrate after a laser radiation step implemented to the mold cap and the substrate according to a fourth embodiment of the present application.

FIG. 5 illustrates a cooling step to cool down a mold cap and a substrate after a laser radiation step implemented to the mold cap and the substrate according to a fifth embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, a semiconductor package may be formed by first mounting electronic components onto a substrate via solder bumps and then forming a mold cap on the substrate to encapsulate the electronic components. The formation of the mold cap may include a curing process to heat a molding material formed on the substrate and transform it into the mold cap. During the heating process, the mold cap and the substrate may deform due to mismatch in the coefficient of thermal expansion (CTE) between the substrate and the mold cap, which originates from a material difference between the substrate and the mold cap. Therefore, after the formation of the mold cap, both of the mold cap and the substrate may have warpage issues. Especially for the mold cap formed of epoxy mold compound (EMC), the CTE of the mold cap may be much larger than that of the substrate. As a result, the mold cap may deform more significantly than the substrate, which may adversely affect device performance and following fabrication processes.

To address this issue, a new method for forming an electronic device is provided. The new method introduces a laser radiation step after a curing step of a molding layer, which can heat a mold cap formed of the molding layer and the substrate to a temperature above a predetermined temperature threshold, so as to allow deformability of the mold cap and the substrate. When a temperature of the mold cap and the substrate is above the predetermined temperature threshold, a vacuum pressure may be applied to the substrate and the mold cap through a carrier underneath the substrate. Therefore, the substrate and the mold cap can be attracted to the carrier, which reduces warpages of the mold cap and the substrate generated during the curing step, thus improving device performance and facilitating following fabrication processes.

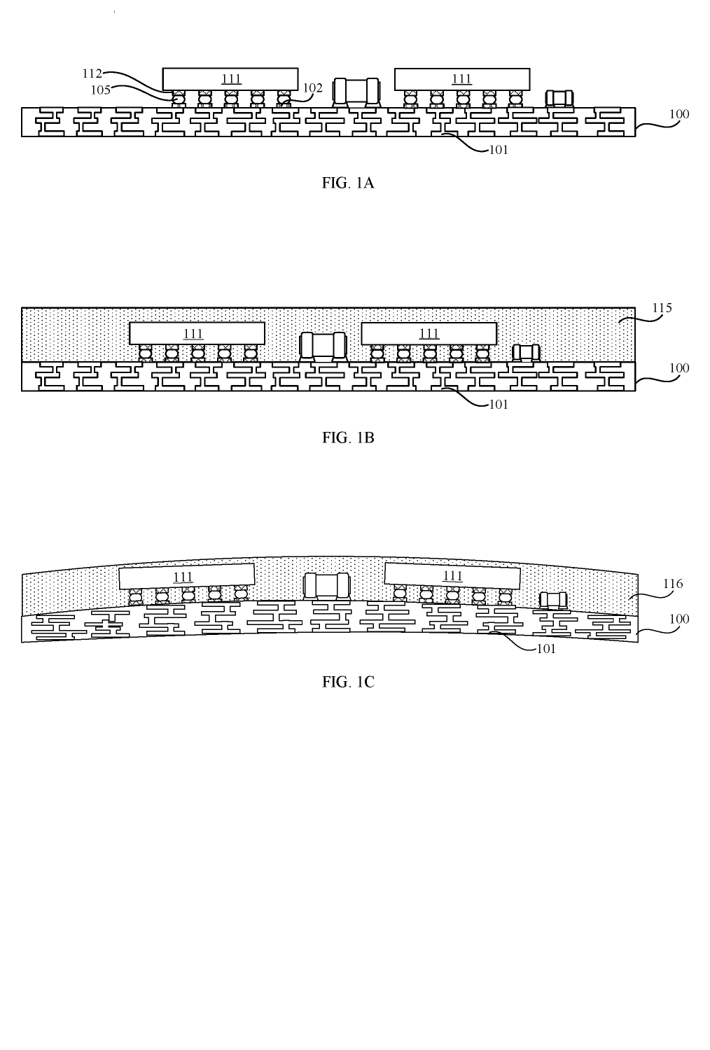

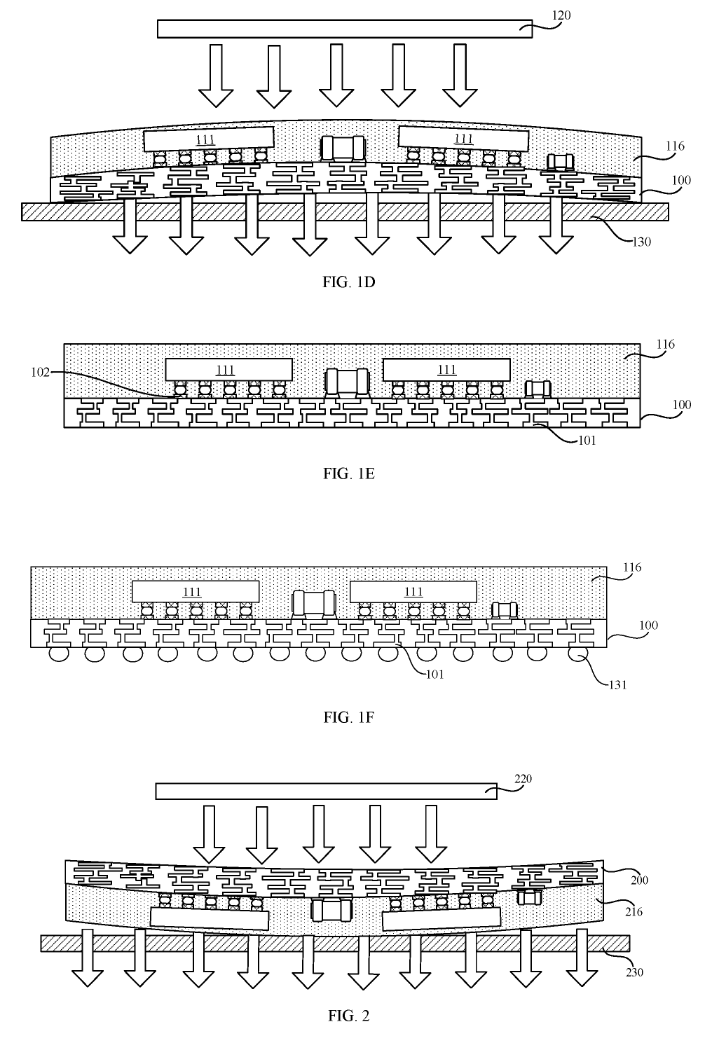

FIGS. 1A to 1F illustrate various steps of a method for forming an electronic device according to a first embodiment of the present application.

As shown in FIG. 1A, a substrate 100 is provided with embedded interconnect wires 101. The substrate 100 includes a front surface, which may serve as a platform where electronic component(s) can be mounted, and a back surface opposite to the front surface. In some embodiments, the substrate 100 may be made of silicon or other semiconductor materials, or may include a printed circuit board (PCB), a carrier substrate, a ceramic substrate, a laminate interposer, a strip interposer, a leadframe, or other suitable substrates. The interconnect wires 101 may be formed between and through the substrate 100. Thus, electronic component(s) and other structures on either one surface or both surfaces of the substrate 100 may be electrically coupled with each other to form an integrated electronic system, which will be elaborated below in more details. In some embodiments, a first set of conductive pads 102 can be formed on the front surface of the substrate 100 for the mounting of the electronic component(s). It also can be appreciated that the first set of conductive pads 102 may be exposed portions of interconnect wires 101 formed within the substrate 100.

Next, a solder paste is attached on each of the first set of conductive pads 102 for the mounting of the electronic component(s). The solder paste may include a metal material or a combination of metal materials. It can be appreciated that a combination of metal and non-metal materials may also be provided within the metal solder. To be more specific, the metal material(s) may be Al, Sn, Ni, Au, Ag, lead (Pb), bismuth (Bi), Cu, or combinations thereof.

Next, the at least one electronic component 111 is disposed onto the front surface of the substrate 100. To be more specific, each of the at least one electronic component 111 may include a second set of conductive pads 112 on its back surface. Each of the second set of conductive pads 112 is aligned with one of the first set of conductive pads 102 with the solder paste disposed therebetween. In some other embodiments, an additional solder paste may be attached on the second set of conductive pads 112. The at least one electronic component 111 may then be disposed on the front surface of the substrate 100 with the solder paste and the additional solder paste disposed between the first and second set of conductive pads 102, 112. In some embodiments, the electronic component 111 may include various types of electronic modules, such as semiconductor chips, resistors, capacitors or other integrated circuit chips. For example, the electronic component 111 may include a semiconductor die. Furthermore, as shown in FIG. 1A, more than one electronic component 111 is mounted on the substrate 100, where the electronic components 111 may have various sizes and be arranged in different layouts. In some embodiments, a flux material may further be applied within the solder paste or dispensed to the first set of the conductive pads 102 to facilitate a subsequent reflowing process.

Next, a heating process, such as thermal convection heating or laser radiation heating may be applied to the substrate 100 to heat the solder paste, such that the solder paste can be heated and reflowed to form solder bumps 105 between the first set of conductive pads 102 and the second set of conductive pads 112. The solder bumps 105 so form can form an electrical connection between the at least one electronic component 111 and the substrate 100. During the heating process of the solder paste, a large amount of heat is directly applied to the substrate 100 and the at least one electronic component 111, which may induce warpage of the substrate 100 tentatively. In particular, in some embodiments where more than one electronic component 111 with various sizes and layouts are mounted on the substrate 100, different portions or positions of the substrate 100 may absorb heat differently due to impacts of the various sizes and layouts of the electronic components 111 mounted thereon, thereby resulting in additional warpage issues of the substrate 100.

In some embodiments, the substrate 100 may be provided in the form of a substrate strip including a plurality of substrate units such that each of the substrate units may serve as a platform where an electronic package can be formed on. The substrate strip may or may not include a plurality of linkage portions, each of which is positioned between two adjacent substrate units, thus connecting the plurality of substrate units as the substrate strip. In this embodiment, each of the substrate units may have the same or similar structure, while the electronic component(s) 111 mounted on the respective substrate units may have different sizes and layouts. It can be appreciated that a plurality of electronic packages may be formed using the same processing on the plurality of substrate units simultaneously. Also, it can be appreciated that in some embodiments, both the linkage portions and the substrate units are originally formed within the substrate strip and are not required to be assembled together as the substrate strip.

Next, as shown in FIG. 1B, a molding layer 115 is formed on the substrate 100 to encapsulate the at least one electronic component 111. To be more specific, the molding layer 115 may be formed using an injection molding process, which covers the front surface of the substrate 100 and respective surfaces of the at least one electronic component 111 for encapsulation. In some other embodiments, the molding layer 115 may be formed using other various molding technologies, including a transfer molding process, a compression molding process or a film-assisted molding (FAM) process, for example. In some embodiments, the molding layer 115 may be epoxy mold compound (EMC). It can also be appreciated that the molding layer 115 may be made of a polymer composite material, such as epoxy resin with filler, epoxy acrylate with filler, or polymer with proper filler, but the scope of this application is not limited thereto.

Next, a heating process is applied to the molding layer 115 and the substrate 100 through convection heat transfer or heat radiation, for example, to heat the molding layer 115 to a temperature above its curing temperature such that the molding layer 115 may be cured and transformed into the mold cap 116. During the heating process, the formed mold cap 116 and the substrate 100 may expand differently, which may be resulted from a mismatch in the coefficient of thermal expansion between the different materials of the mold cap 116 and the substrate 100. As such, warpage issue may occur on both of the mold cap 116 and the substrate 100 tentatively. In particular, in some embodiments where electronic components 111 with various sizes and layouts are mounted on the substrate 100, the molding layer 115 encapsulating the electronic components 111 may absorb heat differently at different positions, thereby resulting in additional warpages of the mold cap 116.

The warpages of the mold cap 116 and the substrate 100 may occur in various forms due to the difference in material between the mold cap 116 and the substrate 100 as well as the various sizes and layouts of the electronic components 111 mounted on the substrate 100. In some embodiments, after the curing step, the mold cap 116 and the substrate 100 may have a convex-shaped structure with respective to a horizontal plane of a working platform or carrier (not shown), as shown in FIG. 1C. To be more specific, in the convex-shaped structure, central portions of the mold cap 116 and the substrate 100 may be higher than peripheral portions of the mold cap 116 and the substrate 100. In some other embodiments, the mold cap 116 and the substrate 100 may have a concave-shaped structure which is opposite to the convex-shaped structure shown in FIG. 1C, where the central portions of the mold cap 116 and the substrate 100 may be lower than the peripheral portions of the mold cap 116 and the substrate 100.

The tentative warpages of the mold cap 116 and the substrate 100 generated during the curing step may be reduced by applying laser radiation and a vacuum pressure to the substrate 100 and the mold cap 116. To be more specific, the laser radiation may be applied to heat the mold cap 116 and the substrate 100 to allow for deformability of the mold cap 116 and the substrate 100 when they are exposed to an external force. In addition, the vacuum pressure may be applied to attract the mold cap 116 and the substrate 100 to a carrier to alleviate the warpage. Details of the laser radiation and the vacuum processing will be elaborated in the following.

As shown in FIG. 1D, the substrate 100 is attached to a carrier 130 with the mold cap 116 facing away from the carrier 130. Since the substrate 100 and the mold cap 116 may have a convex shape, a gap may exist between the central portion of the substrate 100 and the carrier 130 while the peripheral portion of the substrate 100 may be in direct contact with the carrier 130. The carrier 130 includes air vents passing therethrough, which are fluidly connected with a vacuum source to form a vacuum pressure within the air vents. The air vents may be exposed from the front surface of the carrier 130 such that the vacuum pressure can be applied to the substrate 100 through the air vents. In this way, the substrate 100 can be attracted to the substrate 100 by an attraction force generated by the vacuum pressure. Since the mold cap 116 and the substrate 100 are formed as an integrated piece, the mold cap 116 is also attracted downwards to the carrier 130 along with a downward movement of the substrate 100. In some embodiments, the air vents may include a plurality of pores distributed across the whole carrier 130 to provide a uniform vacuum pressure. In some other embodiments, the air vents may include interconnected channels or pipelines therebetween to ensure the uniform vacuum pressure.

Meanwhile, a laser source 120 is positioned above the substrate 100 and the mold cap 116. The laser source 120 may emit laser radiation (e.g., infrared radiation) to the mold cap 116 and the substrate 100 to heat them to a temperature above a predetermined temperature threshold. This may allow for deformability of the mold cap 116 and the substrate 100 when they are subject to an external force or pressure such as the vacuum pressure. The laser radiation provides uniform and rapid heating to the substrate 100 and the mold cap 116. In some embodiments, the predetermined temperature threshold may be 140 °C~180 °C which guarantees suitable deformability of the mold cap 116 and the substrate 100. In some preferred embodiments, the laser radiation from the laser source 120 may be applied with a power ranging from 2000W to 6000W. Also, the laser radiation may be applied for a duration between 1 second to 3 seconds, to allow for a sufficient heating to the substrate 100 and the mold cap 116. It can be appreciated that the laser power and the heating duration may vary significantly depending on the object that needs to be heated. Furthermore, in some embodiments, the vacuum pressure applied to the substrate 100 may change as a function of time, for example, increasing linearly or exponentially with time. The changing vacuum pressure, especially an increasing vacuum pressure may be beneficial when more significant warpages need to be eliminated. In some other embodiments, the vacuum pressure applied to the substrate 100 may change as a function of the temperature of the substrate, for example, increasing linearly or exponentially with the temperature of the substrate 100.

Still referring to FIG. 1D, the front surface of the carrier 130 is a flat surface. Therefore, the substrate 100 with the mold cap 116 can be attracted to the flat surface of the carrier 130 by the vacuum pressure when they are heated to a deformable state. In this way, the attraction force created by the vacuum pressure flattens the substrate 100 and the mold cap 116 by using the flat carrier 130 as a benchmark. The warpages of the substrate 100 and the mold cap 116 may be reduced simultaneously, as shown in FIG. 1E, which finally allows the mold cap 116 and the substrate 100 to have a flat shape and facilitates following fabrication processes. Additionally, dislocation of the electronic component(s) 111 within the mold cap 116 induced by the warpage may be alleviated, and risks of mismatch between the electronic component(s) 111 and the substrate 100, or particular between the first set of conductive pads 102 and the interconnect wires 101 may also be reduced. A better alignment between the first set of the conductive pads and the interconnect wires may greatly improve electrical reliability of the formed electronic package. In some embodiments, the laser radiation applied to the mold cap 116 and the substrate 100 after the curing of the molding layer 115 may be conducted using the same process and apparatus as those used for the curing of the molding layer, thus avoiding additional procedures and achieving a controlled cost. As such, the process to reduce the warpage of the mold cap 116 and the substrate 100, i.e., the application of the laser radiation and the vacuum pressure can be used in mass production scenario to improve performance of the formed electronic packages with a high yield.

In the embodiment shown in FIG. 1D, the laser radiation and the vacuum pressure may be applied simultaneously to flatten the substrate 100 and the mold cap 116. In some other embodiments, the laser radiation may be applied before the application of the vacuum pressure such that the substrate 100 and the mold cap 116 may be heated to a deformable state before an external force is applied to flatten the substrate 100 and the mold cap 116. It can be appreciated that the vacuum pressure may be applied when the temperature of the substrate 100 and the mold cap 116 gradually decreases from the high temperature corresponding to the deformable state to a low temperature such as the room temperature.

In some other embodiments, a heater may be attached onto a bottom surface of the carrier 130. Before being heated by the laser radiation, the substrate 100 and the mold cap 116 may be pre-heated by the heater. In this way, less energy from the laser source 120 may be required during the laser radiation step to heat the mold cap 116 and the substrate 100 to a temperature above a predetermined temperature threshold. Also, a time duration for which the laser radiation is applied may be shortened, which improves process efficiency. In some embodiments, the heater may be heated to a temperature at about 90 °C, while the carrier 130 may be maintained at a temperature at about 70 °C.

In some embodiments, a pressing component such as a lid may be introduced to press the mold cap 116 and the substrate 100 against the carrier 130. The pressing component may be positioned at a top surface of the central portion of the mold cap 116 where the warpage of the mold cap 116 and the substrate 100 is most severe, as illustrated in FIG. 1D. In this way, the warpage of the mold cap 116 and the substrate 100 may be further reduced by an additional pressing force, along with the attraction by the vacuum pressure. It should be noted that the pressing component may have a relatively small size to avoid blocking of the laser radiation to the mold cap 116.

In some embodiments, the air vents of the carrier 130 may have different distributions at various positions of the carrier 130. For the substrate 100 and the mold cap 116 with a convex shape, as shown in FIG. 1D, the air vents of the carrier 130 below the central portion of the substrate 100 may be more densely arranged than those below the peripheral portion of the substrate 100. It can also be appreciated that most or all of the air vents of the carrier 130 below the central portion of the substrate 100 may have a larger size compared with those below the peripheral portion of the substrate 100. In this way, a larger attraction force may be applied to further reduce the warpage of the central portion of the mold cap 116 and the substrate 100. Similarly, in some other embodiments where the substrate 100 and the mold cap 116 have a concave shape, the air vents of the carrier 130 below the peripheral portion of the substrate 100 may be more densely arranged than those below the central portion of the substrate 100. It can also be appreciated that most or all of the air vents of the carrier 130 below the peripheral portion of the substrate 100 may have a larger size compared with those below the central portion of the substrate 100. Additionally, an alignment mark may be formed on the carrier 130 to guarantee the alignment between the substrate 100 and the carrier 130 with respect to the air vents.

Still referring to FIG. 1D, in some other embodiments, the carrier 130 may have a concave shape which is opposite to the convex shape of the substrate 100 and the mold cap 116. In this way, when the substrate 100 and the mold cap 116 are attracted to the carrier 130 by the vacuum pressure, the concave shape of the carrier 130 may provide excessive rectification to the convex-shaped substrate 100, which further offsets the warpage in a better way. Similarly, in some embodiments where the substrate 100 and the mold cap 116 may have a concave shape, a convex-shaped carrier 130 may be used to reduce the warpage. It should be noted that before placing the substrate 100 onto the carrier 130, a precheck step may be conducted to make sure that the carrier 130 to be used has a shape (i.e., the convex shape or concave shape) which is opposite to that of the substrate 100 with the mold cap 116. The precheck step may include acquiring the shape of the substrate 100 with the mold cap 116 via a camera or an infrared sensor. If the substrate 100 and the carrier 130 do not match in shape, then the substrate 100 can be flipped over, so as to fit for placement on the carrier 130. Moreover, an alignment mark may be formed on the carrier 130 to guarantee the alignment between the substrate 100 and the carrier 130 which can compensate for each other.

Next, as shown in FIG. 1E, a cooling step may be conducted to the substrate 100 with the mold cap 116. During the cooling step, the vacuum pressure may be applied continuously to avoid formation of warpage due to the different coefficient of thermal expansion between the substrate 100 and the mold cap 116. Alternatively, the vacuum pressure may not be applied during the cooling step to save cost.

Next, as shown in FIG. 1F, additional solder bumps 131 may be formed on the back surface of the substrate 100 for mounting the substrate 100 onto external electronic modules. In this way, an electronic device with reduced warpages and improved performance can be formed. The solder bumps 131 may be electrically connected with the interconnect wires 101 in the substrate 100, such that the at least one electronic component 111 can be accessed through the additional solder bumps 131.

In some embodiments where a substrate strip with multiple units are processed simultaneously as mentioned above, the substrate strip may be singulated into a plurality of substrate units, thereby forming a plurality of electronic packages in a batch.

In some embodiments where the mold cap 116 may have more serve warpage issue than the substrate 100 due to non-uniform layouts and sizes of the electronic components 111 encapsulated within the mold cap 116, the vacuum pressure may be provided more directly to the mold cap 116 to reduce its warpage, as illustrated below.

FIG. 2 illustrates a laser radiation step to heat a mold cap and a substrate for forming an electronic device according to a second embodiment of the present application. The laser radiation step illustrated in FIG. 2 may be implemented instead of the step illustrated in FIG. 1D, between the steps illustrated in FIGS. 1A to 1C and the steps illustrated in FIGS. 1E and 1F. Therefore, details of the other steps may be referred to the embodiment described with reference to FIGS. 1A to 1F and will not be elaborated below.

As shown in FIG. 2, after a mold cap 216 is formed on a substrate 200, the substrate 200 with the mold cap 216 may be flipped over. Next, the mold cap 216 is placed onto a carrier 230 with the substrate 200 facing away from the carrier 230. Next, laser radiation is applied via a laser source 220 to heat the mold cap 216 and the substrate 200 to a temperature above a predetermined temperature threshold, such as 140 °C~180 °C. Furthermore, a vacuum pressure is applied through the air vents of the carrier 230 such that the mold cap 216 is attracted to the carrier 230 to reduce warpage of the mold cap 216 and the substrate 200 when a temperature of the mold cap 216 and the substrate 200 is above the predetermined temperature threshold. Since the mold cap 216 is in direct contact with the air vents of the carrier 230, the vacuum pressure is directly applied onto the mold cap 216 to reduce the warpage thereof in a more efficient way. In some embodiments, a pressing component may be used to press a peripheral portion of the substrate 200 and mold cap 216 against the carrier 230. It should be noted that the pressing component may have a relatively small size to avoid blocking of the laser radiation to the substrate 200. Moreover, in some other embodiments, the air vents of the carrier 230 below the peripheral portion of the mold cap 216 may be more densely arranged in the carrier 230 compared with those below the central portion of the mold cap 216 to provide a larger attraction force to the mold cap 216.

In some other embodiments, the substrate 200 may first be attached on the carrier 230 (as illustrated in FIG. 1D) and the vacuum pressure may be applied to the substrate 200 to reduce the warpage. During this process, an additional warpage in an opposite direction may occur to the substrate 200 due to a counter force generated within the substrate 200 and the mold cap 216 when they are exposed to an external force. To be more specific, when the substrate 200 and the mold cap 216 with a convex shape are flattened by the external force, a counter force may generate within the substrate 200 and the mold cap 216, which results in an additional warpage with a concave shape. Then the substrate 200 with the mold cap 216 may be flipped over such that the mold cap 216 can be attracted to the carrier 230 and be flattened by the vacuum pressure again from a different side. In this way, the substrate 200 and the mold cap 216 may be flattened by attraction forces from two opposite sides, which helps to reduce the warpage and finally achieves a flat shape of the mold cap 216 and the substrate 200.

More details of the steps of applying the laser radiation and the vacuum pressure may be similar to those illustrated in FIG. 1D, which will not be elaborated below.

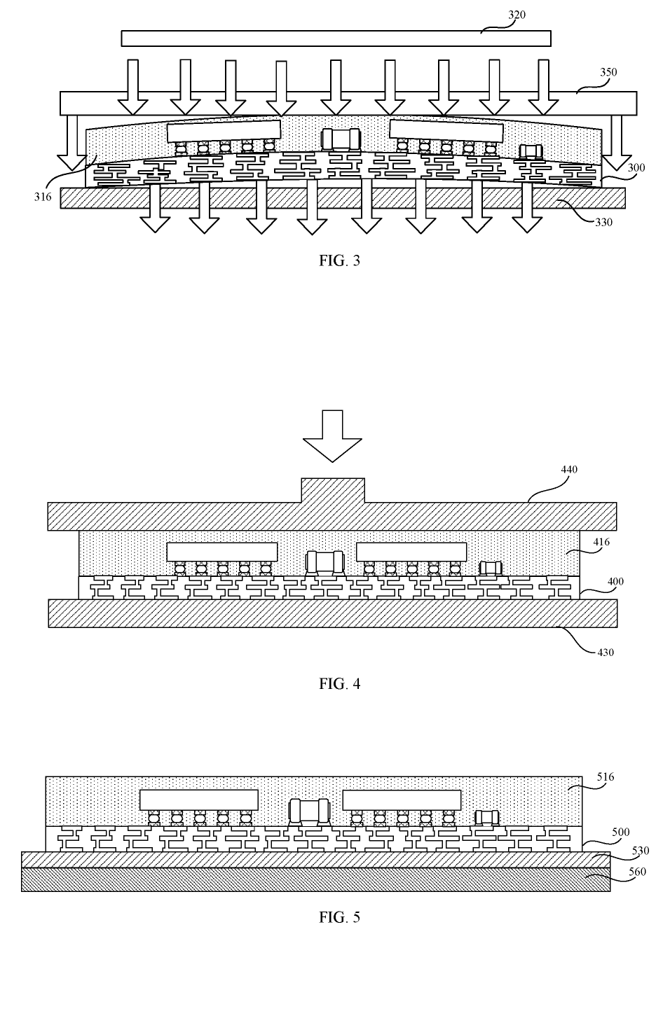

FIG. 3 illustrates a laser radiation step to heat a mold cap and a substrate for forming an electronic device according to a third embodiment of the present application. The laser radiation step illustrated in FIG. 3 may also be an alternative step to either of the laser radiation step illustrated in FIGS. 2 or 1D.

As shown in FIG. 3, a laser compression tool is used to apply the laser radiation to heat a mold cap 316 and a substrate 300. The laser compression tool may include a light pervious component 350 and a laser source 320. To be more specific, the light pervious component 350 is disposed on a top surface of the mold cap 316 and the laser source 320 is disposed above the light pervious component 350. The laser source 320 emits a laser beam through the light pervious component 350 to the mold cap 316 and the substrate 300, so as to heat them to a temperature above a predetermined temperature threshold. In some embodiments, the light pervious component 350 may include glass or quartz. Also, a vacuum pressure is applied to the substrate 300 through the air vents of the carrier 330. When the laser radiation is applied to the mold cap 316, the substrate 300 and the mold cap 316 may be pressed against the carrier 330 via the light pervious component 350 with an external force. As such, a pressing force from the light pervious component 350 and an attraction force from the air vents of the carrier 330 may together generate a larger joint force to push the mold cap 316 and the substrate 300 against the carrier 330. Also, both of the mold cap 316 and the substrate 300 may receive the pressing force or the attraction force directly, which helps to reduce the warpage of the mold cap 316 and the substrate 300 from both sides simultaneously, thus resulting in an improved process efficiency.

In the embodiment shown in FIG. 3, the pressing force via the light pervious component 350, the laser radiation, and the vacuum pressure may be applied to the substrate 300 and the mold cap 316 simultaneously, which reduces the processing time. In some other embodiments, the pressing force, the laser radiation and the vacuum pressure may be applied in a more flexible processing sequence based on actual requirements of reducing the warpages. For example, the laser radiation may be applied before the application of the pressing force by the light pervious component 350 and the vacuum pressure from the carrier 330, such that the substrate 300 and the mold cap 316 may be heated to a deformable state before an external force is applied. It can also be appreciated that the pressing force and the vacuum pressure may be performed simultaneously or sequentially.

In some other embodiments, a fastener such as a clamp may be used to assemble the light pervious component 350 and the carrier 330 together through interference fit to apply a pressing force to the mold cap 316 instead of introducing an additional external force. In some alternative embodiments, the fastener may include two magnetic components each attached to one of the light pervious component 350 and the carrier 330. The two magnetic components can be attracted to each other to assemble the light pervious component 350 and the carrier 330 together.

FIG. 4 illustrates a cooling step to cool down a mold cap and a substrate after a laser radiation step implemented to the mold cap and the substrate according to a fourth embodiment of the present application. The cooling step illustrated in FIG. 4 may be implemented instead of the step illustrated in FIG. 1E, between the steps illustrated in FIGS. 1A to 1D and the step illustrated in FIG. 1F. Therefore, details of the other steps may be referred to the embodiment described with reference to FIGS. 1A to 1F and will not be elaborated below.

As shown in FIG. 4, after laser radiation is implemented to a mold cap 416 and a substrate 400, the substrate 400 and the mold cap 416 are cooled down to a lower temperature. During the cooling step, a pressing component 440 may be introduced to press the mold cap 416 and the substrate 400 against a carrier 430 by an external force, so as to avoid formation of warpage. Moreover, during the cooling step, a vacuum pressure may be applied continuously when the pressing component 440 is pressing the mold cap 416 and substrate 430 against the carrier 430. In some other embodiment, a fastener may also be used to assemble the pressing component 440 and the carrier 430 together through interference fit to apply pressing force to the mold cap 416 instead of introducing an additional external force.

FIG. 5 illustrates a cooling step to cool down a mold cap and a substrate after a laser radiation step implemented to the mold cap and the substrate according to a fifth embodiment of the present application. The cooling step illustrated in FIG. 5 may be implemented instead of the step illustrated in FIG. 1E, between the steps illustrated in FIGS. 1A to 1D and the step illustrated in FIG. 1F. Therefore, details of the other steps may be referred to the embodiment described with reference to FIGS. 1A to 1F and will not be elaborated below.

As shown in FIG. 5, a chiller 560 may be attached to a bottom surface of a carrier 530 to cool the carrier 530 and a substrate 500 placed thereon. During the cooling step, the chiller 560 may reduce a temperature of the carrier 530, and thus helps cooling of the substrate 500 and a mold cap 516 in a shorter period of time. The rapid cooling of the substrate 500 and the mold cap 516 may further reduce the warpage thereof and avoid risks of formation of warpage. In some embodiments, the chiller 560 may include a cooling component such as a heat dissipator, a fan or an air-conditioner.

While the exemplary method for forming an electronic device of the present application is described in conjunction with corresponding figures, it will be understood by those skilled in the art that modifications and adaptations to the method for forming an electronic device may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming an electronic device, the method comprising:
providing a substrate with at least one electronic component mounted thereon;
forming a molding layer on the substrate to encapsulate the at least one electronic component;
curing the molding layer to transform it into a mold cap;
disposing the substrate with the mold cap onto a carrier having air vents passing therethrough;
applying laser radiation via a laser source to heat the mold cap and the substrate to a temperature above a predetermined temperature threshold; and
applying, when the temperature of the mold cap and the substrate is above the predetermined temperature threshold, a vacuum pressure to the substrate and the mold cap through the air vents of the carrier such that the substrate and the mold cap are attracted to the carrier to reduce warpage of the mold cap and the substrate generated during the curing step.

2. The method of claim 1, wherein applying a vacuum pressure to the substrate and the mold cap is performed after applying laser radiation to heat the mold cap and the substrate.

3. The method of claim 1, wherein applying a vacuum pressure to the substrate and the mold cap is performed simultaneously with applying laser radiation to heat the mold cap and the substrate.

4. The method of claim 1, wherein disposing the substrate with the mold cap onto a carrier comprises:
placing the substrate onto the carrier with the mold cap facing away from the carrier.

5. The method of claim 1, wherein disposing the substrate with the mold cap onto a carrier comprises:
placing the mold cap onto the carrier with the substrate facing away from the carrier.

6. The method of claim 1, wherein applying laser radiation to heat the mold cap and the substrate is performed using a laser compression tool having a light pervious component and the laser source, and wherein applying laser radiation to heat the mold cap and the substrate comprises:
disposing the laser compression tool above the mold cap and the substrate;
applying the laser radiation to heat the mold cap and the substrate through the light pervious component via the laser source; and
pressing the substrate and the mold cap against the carrier via the light pervious component.

7. The method of claim 1, after applying laser radiation, the method further comprising:
cooling the substrate and the mold cap.

8. The method of claim 7, wherein cooling the substrate and the mold cap comprises:
cooling the substrate and the mold cap while the vacuum pressure is applied to the substrate.

9. The method of claim 7, wherein cooling the substrate and the mold cap further comprises:
cooling the substrate and the mold cap while the substrate and the mold cap are pressed against the carrier via a pressing component.

10. The method of claim 7, wherein cooling the substrate and the mold cap further comprises:
cooling the substrate and the mold cap via a chiller attached to the carrier.

11. The method of claim 1, wherein before applying laser radiation to heat the mold cap and the substrate, the method comprises:
heating the carrier, the substrate and the mold cap through a heater attached to the carrier.

12. The method of claim 1, wherein applying laser radiation to heat the mold cap and the substrate comprises:
applying the laser radiation with a power of the laser source between 2000W to 6000W.

13. The method of claim 1, wherein applying laser radiation to heat the mold cap and the substrate comprises:
applying the laser radiation for a duration between 1 second to 3 seconds.

14. An electronic device which is formed using the method of claim 1.
